(19) United States
(12) Patent Application Publication
(10) Pub. No.: US 2025/0300270 A1
(43) Pub. Date: Sep. 25, 2025

(54) ENERGY STORAGE POWER SUPPLY

(71) Applicant: SHENZHEN HELLO TECH ENERGY CO., LTD, Shenzhen, Guangdong (CN)

(72) Inventors: Hongliang ZHAO, Shenzhen (CN); Zhongwei SUN, Shenzhen (CN); Gaosong SHEN, Shenzhen (CN); Feiyan LUO, Shenzhen (CN); Qingbin LIN, Shenzhen (CN); Wenhai LIN, Shenzhen (CN); Dong HAN, Shenzhen (CN); Yang WU, Shenzhen (CN)

(21) Appl. No.: 19/230,145

(22) Filed: Jun. 6, 2025

Related U.S. Application Data
(63) Continuation of application No. PCT/CN2025/072827, filed on Jan. 16, 2025.

(30) Foreign Application Priority Data
Nov. 14, 2024 (CN) 202411633032.5
Nov. 14, 2024 (CN) 202422796238.1

(51) Int. Cl. H01M 10/6551; H01M 10/42; H01M 10/613; H01M 10/627; H01M 10/6563; H01M 10/6572; H01M 50/224; H01M 50/251; H01M 50/271; H01M 50/30; H05K 7/20

(52) U.S. Cl. CPC H01M 10/6551; H01M 10/425; H01M 10/613; H01M 10/627; H01M 10/6563; H01M 10/6572; H01M 50/224; H01M 50/251; H01M 50/271; H01M 50/394; H05K 7/20909; H01M 2220/10

(57) ABSTRACT

An energy storage power supply is provided and includes a shell having a receiving chamber, in which the receiving chamber is provided with a first support having one or more first receiving recesses, each of the one or more first receiving recesses having a first via hole at a bottom of the first receiving recess; a battery cell located in the receiving chamber and disposed at the first support, the battery cell including a main body, the main body having an end fitted in a corresponding first receiving recess of the one or more first receiving recesses; a second support fixedly connected to the shell and disposed at a side of the battery cell away from the first support, the battery cell being sandwiched between the first support and the second support; and an inverter located in the receiving chamber and electrically connected to the battery cell.

### CROSS-REFERENCE TO RELATED APPLICATION

This application is a continuation application of International Application No. PCT/CN2025/072827, filed on Jan. 16, 2025, which claims priority to and benefits of Chinese Patent Applications Nos. 202411633032.5 and 202422796238.1, filed with China National Intellectual Property Administration on Nov. 14, 2024, the entire contents of each of which are incorporated herein by reference for all purposes.

### FIELD

The present disclosure relates to the field of energy storage technologies, and in particular, to an energy storage power supply.

### BACKGROUND

With the improvement of living standards, users are demanding higher protection levels and greater power output from portable power supplies.

Currently, after the protection level of portable energy storage is increased, a consequence is that an energy storage power supply requires a larger volume for heat dissipation, but fails to effectively reduce a temperature, resulting in unsatisfactory heat dissipation performance.

### SUMMARY

In view of this, the present disclosure aims to solve at least one of the problems in the related art to some extent. To this end, an objective of the present disclosure is to provide an energy storage power supply.

The present disclosure provides an energy storage power supply. The energy storage power supply includes a shell, a battery module, an inverter, and a fan. The shell has a mounting chamber and is provided with a heat dissipation structure. The battery module is mounted in the mounting chamber. The inverter is mounted in the mounting chamber, thermally coupled to the heat dissipation structure, and electrically connected to the battery module. The fan is mounted at an outer side of the shell. The fan is configured to generate flowing air that flows through the heat dissipation structure.

In some embodiments, the heat dissipation structure includes a plurality of heat dissipation fins disposed at a bottom, and/or a side surface, and/or a top of the shell.

In some embodiments, the plurality of heat dissipation fins are arranged in a radial pattern and have a mounting space formed in a center of the plurality of heat dissipation fins, the fan being mounted in the mounting space.

In some embodiments, the plurality of heat dissipation fins are arranged at a gradient in which an arrangement density of the plurality of heat dissipation fins gradually decreases from a center of the plurality of heat dissipation fins to a periphery of the plurality of heat dissipation fins; and the plurality of heat dissipation fins are arranged at a gradient in which an arrangement height of the plurality of heat dissipation fins gradually increases from the center of the plurality of heat dissipation fins to the periphery of the plurality of heat dissipation fins.

In some embodiments, the fan is a centrifugal fan or an axial flow fan.

In some embodiments, the heat dissipation structure includes a protrusion located in the mounting chamber and fixed on the shell, the protrusion being thermally coupled to a power component of the inverter.

In some embodiments, a thermal conductive layer is disposed between the protrusion and the power component, the protrusion being thermally coupled to the power component of the inverter through the thermal conductive layer.

In some embodiments, the thermal conductive layer has a thickness smaller than 1 mm and thermal conductivity greater than 3 W/m/K.

In some embodiments, the energy storage power supply further includes: a foot pad disposed at a bottom of the shell, the foot pad being configured to be in contact with an external supporting surface to space the bottom of the shell apart from the external supporting surface.

In some embodiments, the energy storage power supply further includes a first cover plate fixedly mounted at the outer side of the shell and covering the fan, the first cover plate having a ventilation hole.

In some embodiments, the first cover plate covers the heat dissipation structure, and includes a first bottom plate and a first side plate surrounding the first bottom plate, an air channel being formed between the heat dissipation structure and the first cover plate; and the ventilation hole includes a first ventilation hole formed at the first bottom plate and a second ventilation hole formed at the first side plate, the air channel being formed between the first ventilation hole and the second ventilation hole.

In some embodiments, the energy storage power supply further includes: a foot pad disposed at a side of the first cover plate facing away from the fan, the foot pad being configured to be in contact with an external supporting surface to space a bottom of the first cover plate apart from the external supporting surface.

In some embodiments, the energy storage power supply further includes a foot pad. A through hole corresponding to the foot pad is formed at a bottom plate of the first cover plate, the foot pad passing through the through hole and the shell to be fixedly disposed at a bottom of the first cover plate. The foot pad is configured to be in contact with an external supporting surface to space the bottom of the first cover plate apart from the external supporting surface.

In some embodiments, the shell includes a first housing and a second housing, the first housing and the second housing being assembled with each other to form the mounting chamber. The inverter is fixed on the first housing. The heat dissipation structure is disposed at the first housing. The battery module is fixed on the second housing.

In some embodiments, the first housing is an aluminum alloy housing, the first housing being thermally coupled to the inverter at an inner side of the first housing, and the heat dissipation structure disposed at an outer side of the first housing.

In some embodiments, the first housing is subjected to anodization.

In some embodiments, the first housing has a receiving cavity, the inverter being fixedly mounted in the receiving cavity.

In some embodiments, the second housing is provided with a panel having a power output port.

In some embodiments, the first housing and the second housing are assembled with each other in an up-down direction, the first housing being disposed at a lower side of the second housing.

In some embodiments, a temperature sensor is mounted at the heat dissipation structure to detect a temperature of the heat dissipation structure, the energy storage power supply being configured to control activation of the fan, deactivation of the fan, or a rotational speed of the fan based on the temperature of the heat dissipation structure.

In some embodiments, the energy storage power supply further includes a semiconductor cooling element having a hot end thermally coupled to the heat dissipation structure and a cold end thermally coupled to the inverter.

In some embodiments, the heat dissipation structure has a mounting recess formed at a side of the heat dissipation structure facing towards the inverter, the semiconductor cooling element being mounted in the mounting recess.

In some embodiments, an outer wall of the mounting chamber has a heat dissipation opening, the heat dissipation structure being mounted at the heat dissipation opening.

In some embodiments, the heat dissipation structure includes a mounting portion and a fixing flange arranged around the mounting portion. The mounting portion extends into the heat dissipation opening. The semiconductor cooling element is mounted at the mounting portion. The fixing flange is fixed on the outer wall of the mounting chamber by a connector to close the heat dissipation opening through the heat dissipation structure.

In some embodiments, the energy storage power supply further includes a heat dissipation support. The inverter includes a circuit board provided with a power component. The heat dissipation support is mounted at the shell, configured to fix the circuit board, and thermally coupled to the power component. The heat dissipation support is further thermally coupled to the heat dissipation structure.

In some embodiments, the heat dissipation support includes a base and a second cover plate. The base includes a second bottom plate and two second side plates. The two second side plates are connected to two ends of the second bottom plate, respectively. A thermal conductive pad is disposed between the second bottom plate and the power component. The second cover plate is connected to the two second side plates, and is provided with a limiting member configured to limit the battery module.

In some embodiments, the energy storage power supply further includes a heat pipe thermally coupled to the heat dissipation structure.

With the energy storage power supply of the present disclosure, the heat dissipation structure is formed at a part of the shell located in the mounting chamber, and the inverter is thermally coupled to the heat dissipation structure. The fan is mounted at the outer side of the shell, and configured to generate the flowing air that flows through the heat dissipation structure. Compared with a natural heat dissipation mode, this configuration of the present disclosure provides better heat dissipation performance for the inverter, while allowing the inverter to be lighter in weight. An introduction of the fan improves a heat dissipation efficiency. At the same time, the shell integrates both heat dissipation and support functions, saving an internal space and reducing manufacturing costs of the energy storage power supply.

Additional aspects and advantages of the present disclosure will be provided at least in part in the following description, or will become apparent at least in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic structural view of an energy storage power supply according to some embodiments of the present disclosure.

FIG. 2 is a disassembled schematic structural view of an energy storage power supply according to some embodiments of the present disclosure.

FIG. 3 is a schematic partial structural view of an energy storage power supply according to some embodiments of the present disclosure.

FIG. 4 is a schematic partial structural view of an energy storage power supply according to some embodiments of the present disclosure.

FIG. 5 is a schematic partial structural view of an energy storage power supply according to some embodiments of the present disclosure.

FIG. 6 is a schematic partial structural view of an energy storage power supply according to some embodiments of the present disclosure.

FIG. 7 is a schematic partial structural view of an energy storage power supply according to some embodiments of the present disclosure.

FIG. 8 is a schematic partial structural view of an energy storage power supply according to some embodiments of the present disclosure.

FIG. 9 is a schematic partial structural view of an energy storage power supply according to some embodiments of the present disclosure.

FIG. 10 is a schematic partial structural view of an energy storage power supply according to some embodiments of the present disclosure.

### DESCRIPTION OF MAIN REFERENCE NUMERALS OF THE ACCOMPANYING DRAWINGS

energy storage power supply 100;
housing 10, bottom 101, side surface 102, top 103, mounting chamber 11, heat dissipation structure 12, heat dissipation fin 121, second snap-fit member 1211, first connection post 1212, mounting space 1201, protrusion 122, thermal conductive layer 123, semiconductor cooling element 124, insulation member 125, mounting recess 126, mounting portion 127, fixing flange 128, seal 129, first housing 13, first engagement member 131, receiving cavity 132, second housing 14, second engagement member 141; battery module 20, protection board 21; inverter 30, circuit board 31, power component 311, thermal conductive pad 312, transformer 3111, inductor 3112, heat dissipation support 32, base 321, second bottom plate 3211, receiving recess 32111, second side plate 3212, heat dissipation winglet 32121, second cover plate 322, limiting member 3221, insulation plate 33; fan 40, first snap-fit member 41; foot pad 50; first cover plate 60, ventilation hole 61, first ventilation hole 611, second ventilation hole 612, first bottom plate 62, first side plate 63, through hole 64.

### DETAILED DESCRIPTION

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the present disclosure.

In the description of the present disclosure, terms “first” and “second” are only used for descriptive purposes, and cannot be understood as indicating or implying relative importance or implicitly indicating the number of indicated technical features. Therefore, the features associated with “first” and “second” may explicitly or implicitly include at least one of the features. In the description of the present disclosure, “plurality” means at least two, unless otherwise specifically defined.

In the description of the present disclosure, it should be noted that, unless otherwise clearly specified and limited, terms such as “install” and “connect” should be understood in a broad sense. For example, it may be a fixed connection or a detachable connection or connection as one piece; mechanical connection, electrical connection, or mutual communication; direct connection or indirect connection through an intermediate; internal communication of two components or the interaction relationship between two components. For those of ordinary skill in the art, the specific meaning of the above-mentioned terms in the present disclosure can be understood according to specific circumstances.

Various embodiments or examples for implementing different structures of the present disclosure are provided below. In order to simplify the description of the present disclosure, components and arrangements of specific examples are described herein. These specific examples are merely for the purpose of illustration, rather than limiting the present disclosure. Further, the same reference numerals and/or reference letters may appear in different examples of the present disclosure for the purpose of simplicity and clarity, instead of indicating a relationship between different embodiments and/or the discussed arrangements.

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the present disclosure.

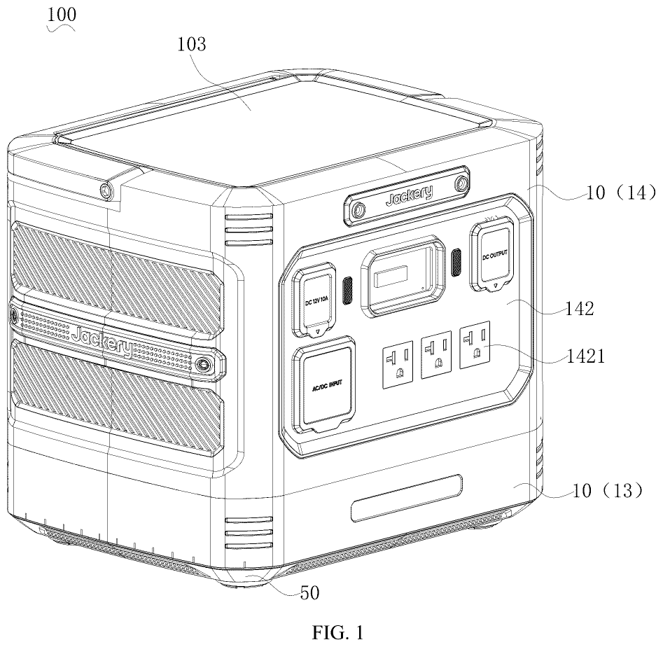

As illustrated in FIG. 1 to FIG. 4, the present disclosure discloses an energy storage power supply 100. The energy storage power supply 100 includes a shell 10, a battery module 20, an inverter 30, and a fan 40. The shell 10 has a mounting chamber 11 and is provided with a heat dissipation structure 12. The battery module 20 is mounted in the mounting chamber 11. The inverter 30 is mounted in the mounting chamber 11, thermally coupled to the heat dissipation structure 12, and electrically connected to the battery module 20. The fan 40 is mounted at an outer side of the shell 10 and configured to generate flowing air that flows through the heat dissipation structure 12.

It should be understood that, since the battery module 20 has a large thermal capacity and generates a relatively small amount of heat, a temperature reduction of the battery module 20 can be realized through natural heat dissipation. In contrast, the inverter 30, which generates a large amount of heat, requires cooperation between the heat dissipation structure 12 disposed at the shell 10 and the fan 40 to realize a temperature reduction. Considering that heat generated during operation of the inverter 30 is transferred to the heat dissipation structure 12, and then transferred to an ambient environment by the fan 40, a temperature of the inverter 30 is reduced, ensuring cooling performance of the energy storage power supply.

That is, the energy storage power supply 100 of the present disclosure utilizes the shell 10 as both a support frame and a heat dissipation member, which eliminates a need for an additional heat dissipation member, thereby reducing an overall height and an overall volume of the energy storage power supply 100, and achieving a high level of protection for the inverter 30.

The shell 10 of the present disclosure may be made of a metallic material to make the resulting energy storage power supply 100 more robust and durable.

A thermal coupling mode between the inverter 30 and the heat dissipation structure 12 may be a direct thermal connection or an indirect thermal connection via an intermediate connection member.

An electrical connection mode between the inverter 30 and the battery module 20 may be a direct electrical connection or an indirect electrical connection. For example, the battery module 20 may be electrically connected to the inverter 30 indirectly through a battery protection board. The battery protection board can provide protection against overvoltage, over-temperature, overcurrent, or the like, and can enable or disable an electrical connection between a battery and an external member.

In this way, with the energy storage power supply 100 of the present disclosure, the heat dissipation structure 12 is formed at the shell 10, and the inverter 30 is thermally coupled to the heat dissipation structure 12. The fan 40 is mounted at the outer side of the shell 10, and configured to generate the flowing air that flows through the heat dissipation structure 12. Compared with a natural heat dissipation mode, this configuration of the present disclosure provides better heat dissipation performance for the inverter 30, while allowing the inverter 30 to be lighter in weight. An introduction of the fan 40 improves a heat dissipation efficiency, At the same time, the shell 10 integrates both heat dissipation and support functions, saving an internal space and reducing manufacturing costs of the energy storage power supply 100.

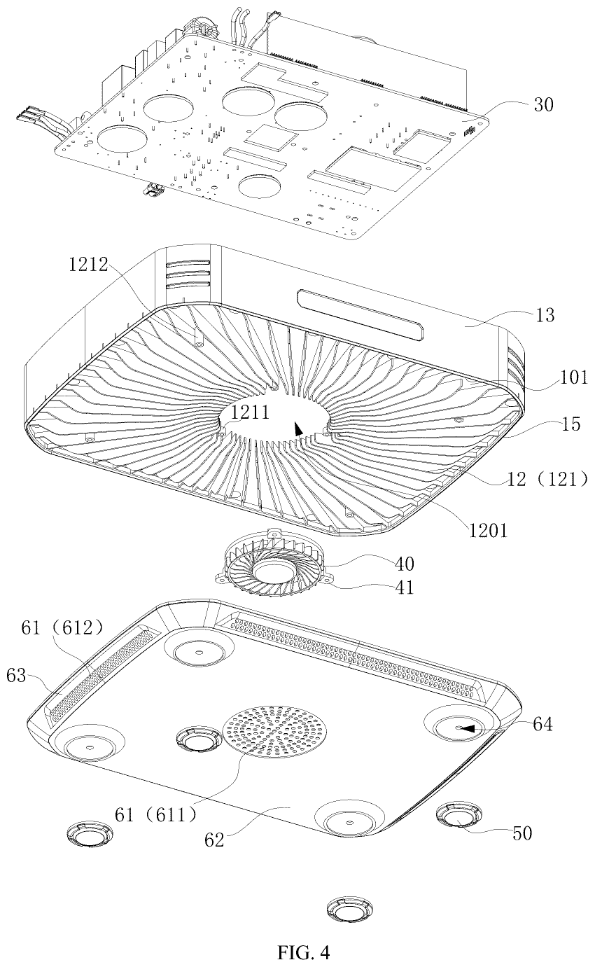

As illustrated in FIG. 4, in some embodiments, the heat dissipation structure 12 includes a plurality of heat dissipation fins 121 disposed at a bottom 101, and/or a side surface 102, and/or a top 103 of the shell 10.

Specifically, the plurality of heat dissipation fins 121 being disposed at the bottom 101, and/or the side surface 102, and/or the top 103 of the shell 10 includes the following situations: (1) the plurality of heat dissipation fins 121 are disposed at any one of the bottom 101, the side surface 102, and the top 103 of the shell 10; (2) the plurality of heat dissipation fins 121 are disposed at any two of the bottom 101, the side surface 102, and the top 103 of the shell 10; and (3) the plurality of heat dissipation fins 121 are disposed at all three of the bottom 101, the side surface 102, and the top 103 of the shell 10.

As illustrated in FIG. 4, when the plurality of heat dissipation fins 121 are disposed at the bottom 101 of the shell 10 of the energy storage power supply 100, the energy storage power supply 100 is aesthetically pleasing as a whole. Additionally, since the heat dissipation fins 121 are disposed at the bottom 101 of the shell 10 of the energy storage power supply 100, a user is less likely to touch the heat dissipation fins 121 and get burned when handling the energy storage power supply 100.

Further, disposing the plurality of heat dissipation fins 121 at the bottom 101 of the shell 10 of the energy storage power supply 100 can also prevent rainwater from entering the mounting chamber 11, providing better waterproofing. In this way, when the energy storage power supply 100 is used outdoors, moisture in air can be prevented from entering the mounting chamber 11 in rainy or humid weather, avoiding short circuits and damage to a circuit board 31 in the inverter 30.

When the plurality of heat dissipation fins 121 are disposed at the side surface 102 or the top 103, electronic components inside the mounting chamber 11 can dissipate heat through the side surface 102 and the top 103 of the shell 10, providing more diversified heat dissipation modes and heat dissipation channels.

In some embodiments, the plurality of heat dissipation fins 121 are arranged in a radial pattern and have a mounting space 1201 formed in a center of the plurality of heat dissipation fins 121, and the fan 40 is mounted in the mounting space 1201.

Specifically, as illustrated in FIG. 4, the fan 40 may be provided with a first snap-fit member 41, and the heat dissipation fin 121 may be provided with a second snap-fit member 1211 engaged with the first snap-fit member 41. The fan 40 is mounted at the center of the plurality of heat dissipation fins 121 by means of a snap-fit connection between the first snap-fit member 41 and the second snap-fit member 1211. The first snap-fit member 41 may be a snap-fit post and the second snap-fit member 1211 may be a snap-fit hole, or alternatively, the first snap-fit member 41 may be a snap-fit hole and the second snap-fit member 1211 may be a snap-fit post. The present disclosure is not limited in this regard.

Since the fan 40 is mounted at the outer side of the shell 10, the fan 40 generates the flowing air that flows through the heat dissipation structure 12, thereby forming a heat dissipation channel. In this way, heat dissipation for the inverter 30 in the mounting chamber 11 can be achieved. Alternatively, since the mounting space 1201 is cooperatively formed by an end of each of the plurality of heat dissipation fins 121 and the fan 40 is mounted in the mounting space 1201, a heat dissipation airflow can be in contact with the plurality of heat dissipation fins 121 from all directions during rotations of the fan 40, which is more conducive to enhancing the heat dissipation performance of the plurality of heat dissipation fins 121.

In this case, regardless of whether the heat dissipation fins 121 are disposed at the bottom 101, the side surface 102, or the top 103 of the shell 10, the fan 40 can be disposed at a center of the outer side of the shell 10, and the heat dissipation fins 121 can be arranged at intervals around the fan 40. Therefore, the shorter and more direct heat dissipation channel and a larger heat dissipation area are formed, resulting in satisfactory heat dissipation performance.

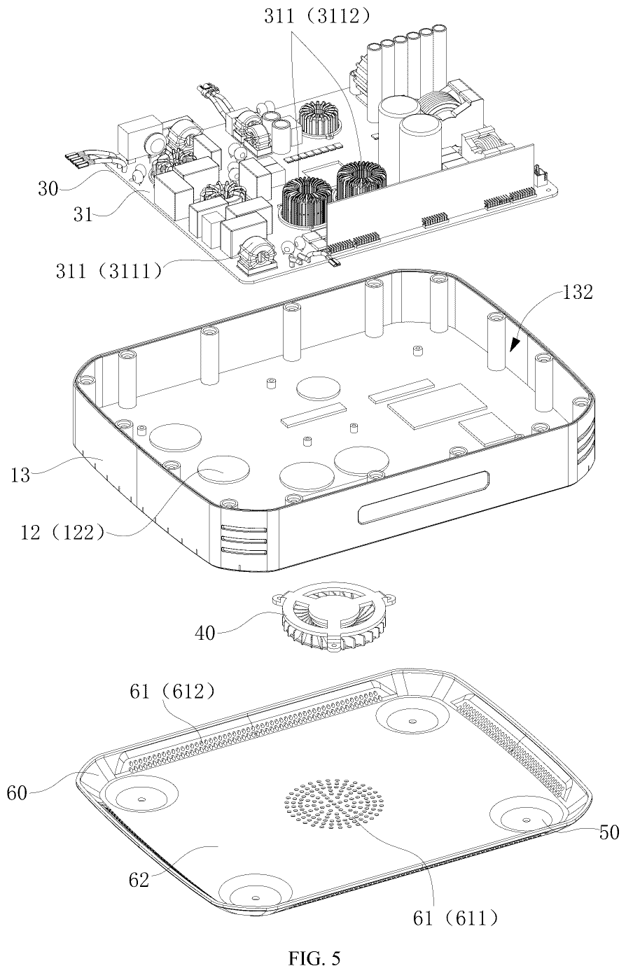

As illustrated in FIG. 5, in some embodiments, the heat dissipation fins 121 are arranged at a gradient in which an arrangement density of the heat dissipation fins 121 gradually decreases from a center of the heat dissipation fins 121 to a periphery of the heat dissipation fins 121. The heat dissipation fins 121 are arranged at a gradient in which an arrangement height of the heat dissipation fins 121 gradually increases from the center of the heat dissipation fins 121 to the periphery of the heat dissipation fins 121.

Specifically, since the central internal region of the heat dissipation fins 121 is close to a heat source and has high heat generation power, the heat dissipation fins 121 are designed to be relatively dense. This dense layout of the heat dissipation fins 121 can increase the heat dissipation area within a limited space, allowing for more efficient absorption and conduction of heat. Although the heat dissipation fins 121 are densely arranged, a height of the heat dissipation fins 121 is relatively low. In this way, on one hand, a rational internal layout within the limited space can be ensured to avoid excessive space occupation due to a greater height of the heat dissipation fins 121, which prevents mounting and layouts of other components from being affected. On the other hand, the relatively low height of the heat dissipation fins 121 also facilitates faster heat conduction to the outside, which prevents heat accumulation in the central internal region of the heat dissipation fins 121 and promotes heat dispersion towards a surrounding region of the outer side of the shell 10, achieving better heat dissipation performance.

The central internal region of the heat dissipation fins 121 have the greater height relative to the outer region of the heat dissipation fins 121, for a reason that a space outside the heat dissipation fins 121 is relatively more spacious. The greater height of the heat dissipation fins 121 can facilitate more efficient heat exchange with surrounding air, improving the heat dissipation efficiency. In addition, the heat dissipation fins 121 in the outer region are arranged to be relatively sparse, which can help reduce an overall weight of the heat dissipation member while ensuring the heat dissipation performance. Additionally, the sparse layout of the heat dissipation fins 121 can reduce use of materials to lower costs and make the heat dissipation member lighter to facilitate mounting and carrying.

A gradual transition from the dense layout of inner parts of the heat dissipation fins 121 to the sparse layout of outer parts of the heat dissipation fins 121 features a gradual angle variation that may range from 10° to 15°.

Accordingly, the energy storage power supply 100 of the present disclosure can effectively achieve a uniform heat distribution through the gradual transition design of the heat dissipation fins 121, which are dense and low in an inner region and high and sparse in an outer region. After heat is generated from the heat source such as the inverter 30, the heat is rapidly absorbed and conducted by the heat dissipation fins 121 of the shell 10 that are densely located in the central internal region, and then gradually diffuses outwards. Since the heat dissipation fins 121 in the outer region are high and sparse, more efficient heat exchange with the air is enabled, allowing the heat to be evenly dissipated into a surrounding environment and preventing localized overheating.

Further, the gradual transition design of the heat dissipation fins 121, which are dense and low in the inner region and high and sparse in the outer region, can not only ensure satisfactory heat dissipation performance but also realize a weight reduction, contributing to an overall lightweight design of the high-protection inverter in a portable power supply.

In some embodiments, the fan 40 may be a centrifugal fan or an axial flow fan.

Specifically, when the axial flow fan is in operation, blades of the axial flow fan pushes air to flow in a same direction as an axis, i.e., an air inlet direction is parallel to an air outlet direction. Typically, the axial flow fan provides a large air volume, which helps rapidly remove heat from an interior of the energy storage power supply, achieving effective heat dissipation. With a relatively simple structure and low manufacturing costs, the axial flow fan provides satisfactory cost-effectiveness. The axial flow fan is suitable for heat dissipation requirements of most energy storage power supplies, especially in applications where a large air volume is needed for rapid heat dissipation.

When the centrifugal fan is in operation, blades of the centrifugal fan push air to move in a direction perpendicular to the axis (i.e., a radial direction), i.e., the air inlet direction is perpendicular to the air outlet direction. The centrifugal fan can generate a high air pressure, which helps to expel the heat from the interior of the energy storage power supply, particularly in applications with a long heat dissipation channel or a high heat dissipation resistance. The centrifugal fan is capable of changing a flowing direction of the airflow to discharge the airflow in the direction perpendicular to the axis, which is particularly useful in some specific heat dissipation designs. Under a same size and other comparable performance conditions, noise of the centrifugal fan is usually lower than that of the axial flow fan, which helps to improve overall use experience of the energy storage power supply. The centrifugal fan is suitable for heat dissipation applications where the airflow needs to be redirected at a 90-degree angle or where a higher air pressure is required.

When the fan 40 is the centrifugal fan, effective air flowing in a small space can be realized by the centrifugal fan due to a characteristic that the air inlet direction of the centrifugal fan is perpendicular to the air outlet direction of the centrifugal fan. Consequently, in the design of the energy storage power supply 100, a position and an orientation of the centrifugal fan can be arranged more flexibly to adapt to an internal spatial layout of the energy storage power supply 100. Therefore, by optimizing a layout and the orientation of the fan, a limited internal space of the energy storage power supply 100 can be utilized more efficiently. For example, the centrifugal fan may be mounted at a side surface or a top of the power supply, avoiding the excessive space occupation at a front, a back, or a bottom of the energy storage power supply 100. This layout not only reduces the overall volume of the energy storage power supply 100 but also helps to lower a height of the energy storage power supply 100, making a structure of the energy storage power supply 100 more compact and portable.

That is, due to the characteristic that the air inlet direction of the centrifugal fan is perpendicular to the air outlet direction of the centrifugal fan, more flexible space utilization can be realized in the design of the energy storage power supply 100, effectively reducing the overall volume and the overall height of the energy storage power supply 100. This design not only improves structural compactness and portability of the energy storage power supply 100, but also improves the heat dissipation efficiency of the energy storage power supply 100 and extends a service life of the energy storage power supply 100.

In addition, the fan 40 can achieve an IP68 protection rating through processes such as potting and vacuum coating of printed circuit board components inside the fan. In this way, the fan 40 can have satisfactory dustproof and waterproof performance, enabling the fan 40 to adapt to harsh work environments while ensuring normal heat dissipation and operation of the energy storage power supply 100.

As illustrated in FIG. 5, in some embodiments, the heat dissipation structure 12 further includes a protrusion 122 located in the mounting chamber 11 and fixed on the shell 10. The protrusion 122 is thermally coupled to a power component of the inverter 30.

It should be understood that when surfaces of two solids come into contact, factors such as surface roughness and gaps may hinder heat transfer between the two solids. This hindrance is known as a thermal contact resistance.

Due to a relatively large contact area between the protrusion 122 and the power component 311 of the inverter 30, and the design of the protrusion 122 can help to reduce presence of gaps and air, the thermal contact resistance between the inverter 30 and the shell 10 can be reduced. That is, a hindrance to heat transfer between the inverter 30 and the shell 10 is decreased, improving a heat dissipation efficiency of the power component 311 of the inverter 30.

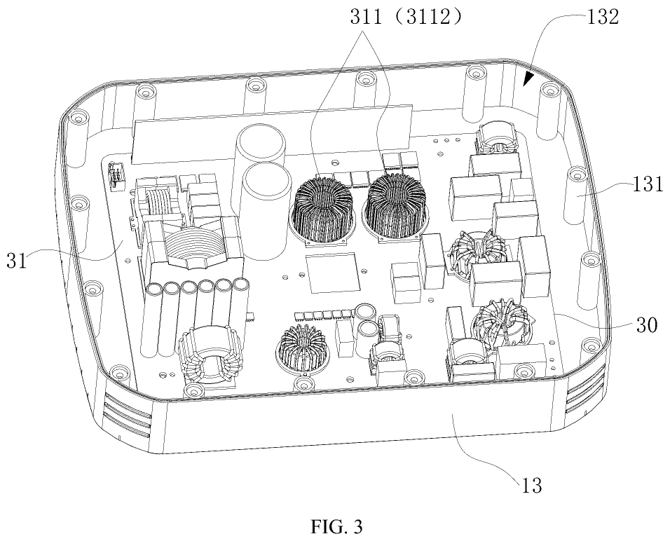

Specifically, with reference to FIG. 3, the power component 311 of the inverter 30 includes elements such as a transformer 3111 and an inductor 3112. The power components 311 such as the transformer 3111 and the inductor 3112 may be mounted and arranged as close as possible to the protrusion 122 at the shell 10, to fully utilize a function of the protrusion 122 in reducing the thermal contact resistance between the inverter 30 and the shell 10.

Therefore, in the present disclosure, the protrusion 122 disposed in and at a bottom of the mounting chamber 11 can be in thermal coupling contact with the power component 311 of the inverter 30, to reduce the thermal contact resistance between the inverter 30 and the shell 10, and improve the heat dissipation efficiency of the power component 311 of the inverter 30.

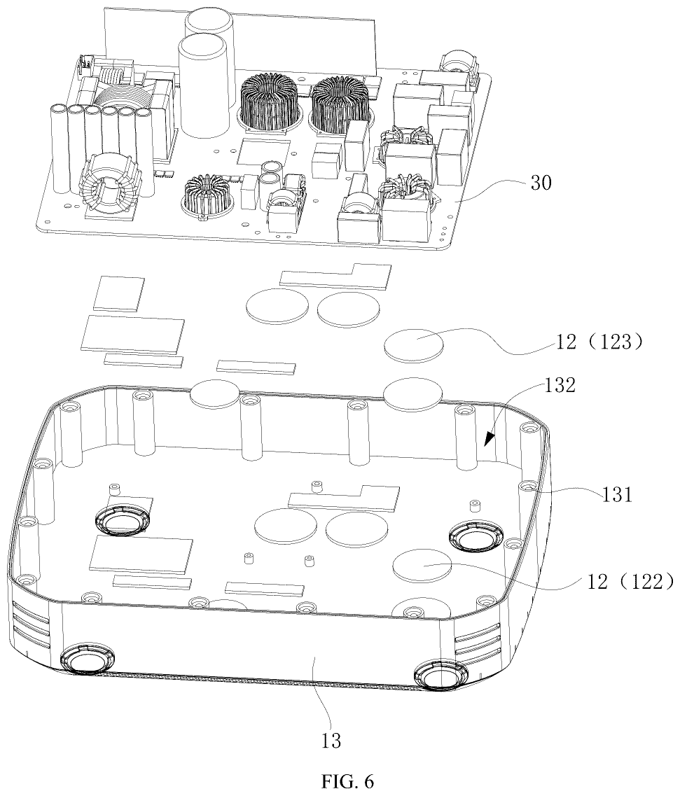

As illustrated in FIG. 6, in some embodiments, a thermal conductive layer 123 is disposed between the protrusion 122 and the power component 311. The protrusion 122 is thermally coupled to the power component 311 of the inverter 30 through the thermal conductive layer 123.

Specifically, the thermal conductive layer 123 may be a thermal pad, a thermal conductive gel, or other thermal conductive structures formed from materials having high thermal conductivity. The present disclosure is not limited to any of these examples.

In this way, with the energy storage power supply 100 of the present disclosure, by forming the thermal conductive layer, which is made of a flexible material, between the protrusion 122 at an inner side of the shell 10 and the power component 311, better attachment can be realized between the power component 311 of the inverter 30 and the protrusion 122 to accelerate a heat conduction process between the inverter 30 and the protrusion 122, speeding up heat conduction from the inverter 30 to the shell 10 for heat dissipation.

In some embodiments, the thermal conductive layer 123 has a thickness smaller than 1 mm and thermal conductivity greater than 3 W/m/K.

It should be understood that an excessive height of the thermal conductive layer 123 can reduce a thermal conduction efficiency between the inverter 30 and the protrusion 122.

Therefore, in the present disclosure, the thickness of the thermal conductive layer 123 can be set to be smaller than 1 mm and the thermal conductivity of the thermal conductive layer 123 can be set to be greater than 3 W/m/K, which can ensure the thermal conduction efficiency between the inverter 30 and the protrusion 122, guaranteeing rapid heat conduction from power components such as the circuit board of the inverter 30 to the shell 10.

That is, by forming the protrusion 122 at the inner side of the shell 10 inside the mounting chamber 11, a height of the thermal conductive layer 123 can be reduced, achieving the optimal thermal conduction efficiency between the inverter 30 and the shell 10.

As illustrated in FIG. 1, in some embodiments, the energy storage power supply 100 further includes a foot pad 50 disposed at a bottom 101 of the shell 10. The foot pad 50 is configured to be in contact with an external supporting surface to space the bottom 101 of the shell 10 apart from the external supporting surface.

Specifically, disposing the foot pad 50 at the bottom 101 of the shell 10 not only prevents the heat dissipation structure 12 from being visible from an outer side of the energy storage power supply 100 to obtain an aesthetically pleasing appearance, but also allows a driven airflow between the fan 40 and the heat dissipation structure 12 to circulate within a relatively ample space, ensuring the heat dissipation efficiency of the heat dissipation structure 12 at the shell 10.

Additionally, the energy storage power supply 100 of the present disclosure is supported by the foot pad 50, in such a manner that the user is less likely to touch the fan 40, improving safety in use of the energy storage power supply 100.

Alternatively, four foot pads 50 are provided and located at four corners of the shell 10, respectively. In this way, stability of the energy storage power supply 100 at the external supporting surface can be ensured. Of course, in other embodiments of the present disclosure, a quantity of foot pads 50 can be adjusted as desired and is not limited to four.

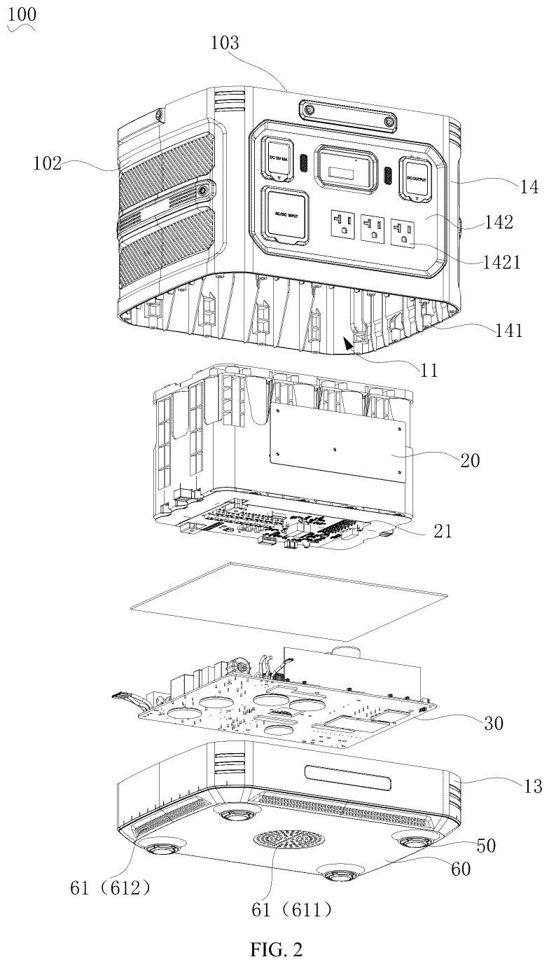

With reference to FIG. 2, in some embodiments, the energy storage power supply 100 further includes a first cover plate 60. The first cover plate 60 is fixedly mounted at the outer side of the shell 10 and covers the fan 40. The first cover plate 60 has a ventilation hole 61.

That is, a position of the first cover plate 60 corresponds to that of the fan 40. When the fan 40 is mounted at the bottom 101 of the shell 10, the first cover plate 60 also covers the bottom 101 of the shell 10. When the fan 40 is mounted at the side surface 102 of the shell 10, the first cover plate 60 also covers the side surface 102 of the shell 10. When the fan 40 is mounted at the top 103 of the shell 10, the first cover plate 60 also covers the top 103 of the shell 10.

The arrangement in which the first cover plate 60 of the present disclosure is fixedly mounted at the outer side of the shell 10 and covers both the fan 40 and the heat dissipation fin 121 can prevent the fan 40 and the heat dissipation fin 121 from being exposed, which can not only protect the fan 40, but also prevent the user from coming into contact with the heat dissipation fin 121 and getting burned while handling the energy storage power supply 100. In addition, the first cover plate 60 also provides an aesthetically pleasing appearance. The first cover plate 60 may be fixedly mounted at the outer side of the shell 10 using a screw or other components. The present disclosure is not limited in this regard.

Since the first cover plate 60 of the present disclosure has the ventilation hole 61, the heat generated by the inverter 30 can be expelled by the fan 40 to the ambient environment through the ventilation hole 61 at the first cover plate 60, achieving heat dissipation for the heat conducted from the inverter 30 to the shell 10.

In some embodiments, the first cover plate 60 includes a first bottom plate 62 and a first side plate 63 surrounding the first bottom plate 62. An air channel is formed between the heat dissipation structure 12 and the first cover plate 60. The ventilation hole 61 includes a first ventilation hole 611 formed at the first bottom plate 62 and a second ventilation hole 612 formed at the first side plate 63. The air channel is formed between the first ventilation hole 611 and the second ventilation hole 612.

Specifically, both the first ventilation hole 611 and the second ventilation hole 612 are formed at the first cover plate 60, i.e., the first cover plate 60 having ventilation holes in two directions, which can create an independent air channel between the first cover plate 60 and the shell 10, enabling faster heat dissipation for the energy storage power supply 100 of the present disclosure.

As illustrated in FIG. 4, a plurality of first ventilation holes 611 may be provided and arranged in an array. Similarly, a plurality of second ventilation holes 612 may be provided and arranged in an array. It should be understood that ventilation performance becomes better as a quantity or an aperture size of the first ventilation holes 611 and the second ventilation holes 612 increases, resulting in better overall heat dissipation performance.

In this way, for the energy storage power supply 100 of the present disclosure, the independent air channel is formed between the first cover plate 60 and the shell 10 through the first ventilation hole 611 and the second ventilation hole 612 at the first cover plate 60, achieving better heat dissipation performance of the heat dissipation structure 12 at the shell 10.

In some embodiments, the first ventilation hole 611 functions as an air inlet, and the second ventilation hole 612 functions as an air outlet; or alternatively, the second ventilation hole 612 functions as the air inlet, and the first ventilation hole 611 functions as the air outlet.

That is, in the present disclosure, the first ventilation hole 611 can function either as the air inlet or the air outlet. When functioning as the air inlet, the first ventilation hole 611 introduces external cool air into the power supply; when functioning as the air outlet, the first ventilation hole 611 expels hot air inside the power supply. Similarly, the second ventilation hole 612 can also function as either the air inlet or the air outlet. When functioning as the air inlet, the second ventilation hole 612 introduces the external cool air into the power supply; when functioning as the air outlet, the second ventilation hole 612 expels the hot air inside the power supply. A specific choice depends on heat dissipation requirements and an internal airflow path of the energy storage power supply 100.

In the present disclosure, each of the first ventilation hole 611 and the second ventilation hole 612 can be controlled to be used as the air inlet or the air outlet through controlling a rotational direction of the fan 40.

Further, a grille may be provided at the first ventilation hole 611 or the second ventilation hole 612. The grille serves both to dissipate heat from the energy storage power supply 100 and to prevent foreign objects from entering an interior of the first cover plate 60 of the energy storage power supply 100.

In some embodiments, the energy storage power supply 100 includes a foot pad disposed at a side of the first cover plate 60 facing away from the fan 40. The foot pad is configured to be in contact with an external supporting surface to space a bottom of the first cover plate 60 apart from the external supporting surface.

That is, in the present disclosure, the foot pad can be directly disposed at the bottom of the first cover plate 60, which not only prevents the heat dissipation structure 12 from being visible from the outer side of the energy storage power supply 100 to obtain the aesthetically pleasing appearance, but also allows the driven airflow between the fan 40 and the heat dissipation structure 12 to circulate within the relatively ample space, ensuring the heat dissipation efficiency of the heat dissipation structure 12 at the shell 10.

Alternatively, four foot pads 50 are provided and located at four corners of the first cover plate 60, respectively. In this way, the stability of the energy storage power supply 100 at the external supporting surface can be ensured. Of course, in other embodiments of the present disclosure, the quantity of foot pads 50 can be adjusted as desired and is not limited to four.

With reference to FIG. 2 and FIG. 4, in some embodiments, the energy storage power supply 100 includes a foot pad 50. A through hole 64 corresponding to the foot pad 50 is formed at the first bottom plate 62 of the first cover plate 60. The foot pad 50 passes through the through hole 64 and the shell 10 to be fixedly disposed at a bottom of the first cover plate 60. The foot pad 50 is configured to be in contact with an external supporting surface to space the bottom of the first cover plate 60 apart from the external supporting surface.

In an embodiment, as illustrated in FIG. 4, when the shell 10 is provided with the heat dissipation fin 121 at the bottom of the shell 10, the heat dissipation fin 121 may be provided with a first connection post 1212, and the foot pad 50 may have a first connection hole corresponding to the first connection post 1212. The foot pad 50 may be fixed on the bottom of the shell 10 through an engagement between the first connection hole and the first connection post 1212, in such a manner that a pressure applied to the foot pad 50 can be transmitted directly to the shell 10 rather than being borne by the first cover plate 60, further effectively preventing damage to the first cover plate 60.

In another embodiment, when the shell 10 is provided with the heat dissipation fin 121 at the bottom of the shell 10, the heat dissipation fin 121 may also have a second connection hole, and the foot pad 50 may be provided with a second connection post 52 corresponding to the second connection hole. The foot pad 50 may be fixed to the bottom of the shell 10 through an engagement between the second connection post 52 and the second connection hole, in such a manner that the pressure applied to the foot pad 50 can be transmitted directly to the shell 10 rather than being borne by the first cover plate 60, further effectively preventing damage to the first cover plate 60.

In yet another embodiment, the foot pad 50 may be provided with a first snap post corresponding to the through hole 64, and the shell 10 may be provided with a second snap post having a snap hole and corresponding to the first snap post. In this way, the first snap post can pass through the through hole 64 to be engaged with the second snap post, allowing the foot pad 50 to penetrate the first cover plate 60 to be firmly mounted to the shell 10. Therefore, the pressure applied to the foot pad 50 can be transmitted directly to the shell 10 rather than being borne by the first cover plate 60, further effectively preventing damage to the first cover plate 60.

Similarly, disposing the foot pad 50 at the bottom of the first cover plate 60 not only prevents the heat dissipation structure 12 from being visible from the outer side of the energy storage power supply to obtain the aesthetically pleasing appearance, but also allows the driven airflow between the fan 40 and the heat dissipation structure 12 to circulate within the relatively ample space, ensuring the heat dissipation efficiency of the heat dissipation structure 12 at the shell 10.

Alternatively, four foot pads 50 are provided and located at four corners of the first cover plate 60, respectively. In this way, the stability of the energy storage power supply 100 at the external supporting surface can be ensured. Of course, in other embodiments of the present disclosure, the quantity of foot pads 50 can be adjusted as desired and is not limited to four.

With reference to FIG. 2, in some embodiments, the shell 10 includes a first housing 13 and a second housing 14. The first housing 13 and the second housing 14 are assembled with each other to form the mounting chamber 11. The inverter 30 is fixed on the first housing 13. The heat dissipation structure 12 is disposed at the first housing 13. The battery module 20 is fixed on the second housing 14.

Specifically, the first housing 13 functions as a lower housing, and the second housing 14 functions as an upper housing. The first housing 13 may be provided with a first engagement member 131, and the second housing 14 may be provided with a second engagement member 141 engaged with the first engagement member 131. The first engagement member 131 may be a hollow first snap-fit post as illustrated in FIG. 3, and the second engagement member 141 may be a solid second snap-fit post, correspondingly engaged with the first snap-fit post, as illustrated in FIG. 2.

Each of the first housing 13 and the second housing 14 of the present disclosure may be formed through die casting, resulting in a simple structure and convenient manufacturing.

The shell 10 of the present disclosure is designed as a spliced structure formed by joining the first housing 13 and the second housing 14, which facilitates an assembly of the energy storage power supply 100.

It should be understood that, when the shell 10 is designed as the spliced structure, the corresponding heat dissipation structure 12 at the shell 10 may also be or may not be a spliced structure. The present disclosure is not limited in this regard.

With reference to FIG. 4, in some embodiments, the first housing 13 is an aluminum alloy housing. The first housing 13 is thermally coupled to the inverter 30 at an inner side of the first housing 13. The heat dissipation structure 12 is disposed at an outer side of the first housing 13.

It should be understood that, since the first housing 13 is the aluminum alloy housing and an aluminum alloy has satisfactory thermal conduction performance, the first housing 13 made of the aluminum alloy also exhibits satisfactory heat dissipation performance. Further, since the heat dissipation structure 12 is disposed at the outer side of the first housing 13, the heat dissipation structure 12 is also made of the aluminum alloy, providing correspondingly satisfactory heat dissipation performance for the heat dissipation structure 12 of the present disclosure.

Additionally, due to a low density of the aluminum alloy and high strength of the aluminum alloy compared to traditional metallic materials such as steel and copper, the first housing 13 made of the aluminum alloy provides robust strength and is less prone to damage from collisions.

In some embodiments, the first housing 13 is subjected to anodization.

Specifically, performing the anodization on the first housing 13 can enhance corrosion resistance of the first housing 13 while improving a surface emissivity of the first housing 13, improving a radiation capability of the first housing 13.

With reference to FIG. 3 and FIG. 5, in some embodiments, the first housing 13 has a receiving cavity 132, and the inverter 30 is fixedly mounted in the receiving cavity 132.

Specifically, the inverter 30 may be fixedly mounted inside the receiving cavity 132 using a screw or a bolt or through other modes. The present disclosure is not limited in this regard.

In this way, the inverter 30 of the present disclosure can be fixedly mounted inside the receiving cavity 132, which can allow heat to be dissipated by the heat dissipation structure 12 disposed at the outer side of the first housing 13, achieving satisfactory heat dissipation performance.

With reference to FIG. 1 and FIG. 2, in some embodiments, the second housing 14 is provided with a panel 142 having a power output port 1421.

That is, the energy storage power supply 100 of the present disclosure can output electrical power externally through the power output port 1421 located at the panel 142 of the second housing 14.

In some embodiments, the first housing 13 and the second housing 14 are assembled with each other in an up-down direction, and the first housing 13 is disposed at a lower side of the second housing 14.

That is, the shell 10 of the present disclosure may be formed by two halves assembled with each other in the up-down direction, which results in a simple structure, facilitating mass production of the shell 10.

In addition, since the heat dissipation structure 12 is disposed at the outer side of the first housing 13 and the first housing 13 is disposed at the lower side of the second housing 14, the heat dissipation structure 12 is equivalent to being disposed at a lower side of the shell 10 in the energy storage power supply 100 of the present disclosure, which makes the heat dissipation structure 12 less likely to be accidentally touched, protecting the heat dissipation structure 12 from damage.

In some embodiments, a temperature sensor is mounted at the heat dissipation structure 12 to detect a temperature of the heat dissipation structure 12. The energy storage power supply 100 is configured to control activation of the fan 40, deactivation of the fan 40, or a rotational speed of the fan 40 based on the temperature of the heat dissipation structure 12.

That is, in the energy storage power supply 100 of the present disclosure, a temperature sensor may be further mounted at the shell 10. After the temperature sensor detects that the temperature of the heat dissipation structure 12 is greater than or equal to a first threshold, the energy storage power supply 100 can automatically control activation of the fan 40, which prevents the temperature of the heat dissipation structure 12 from being too high, facilitating timely heat dissipation for the energy storage power supply 100.

When the temperature sensor detects that the temperature of the heat dissipation structure 12 is smaller than or equal to a second threshold, the energy storage power supply 100 can automatically control deactivation of the fan 40, which facilitates an improvement of a heat dissipation efficiency of the fan 40, reducing power consumption.

For example, the first threshold may be 38°, 39°, 40°, 43°, 45°, 48°, 50°, 51°, 55°, or 60°. The present disclosure is not limited to any of these examples.

For example, the second threshold may be 28°, 29°, 29.5°, 30°, 31°, 34°, 35°, 36°, 37°, or 38°. The present disclosure is not limited to any of these examples.

In this way, in the present disclosure, by disposing the temperature sensor at the heat dissipation structure 12 to timely sense the temperature of the heat dissipation structure 12, the energy storage power supply 100 can promptly control activation of the fan 40 for heat dissipation and promptly control deactivation of the fan 40 for a stop of heat dissipation.

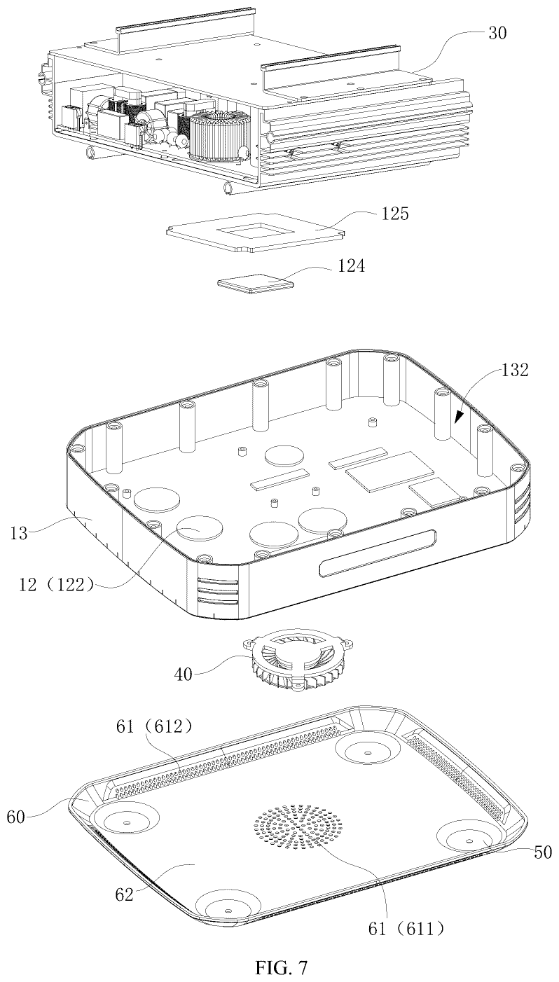

With reference to FIG. 7, in some embodiments, the energy storage power supply 100 further includes a semiconductor cooling element 124 having a hot end thermally coupled to the heat dissipation structure 12 and a cold end thermally coupled to the inverter 30.

It should be understood that the heat dissipation structure 12 may include the semiconductor cooling element 124. Semiconductor cooling technology is an efficient cooling and heat pump solution that utilizes a semiconductor material as a refrigerant, generating a refrigeration effect through an action of an electric current. This technology boasts advantages such as energy efficiency, environmental friendliness, compact size, and satisfactory cooling performance, making it widely applicable across various fields. The principle behind the semiconductor cooling technology involves transfer of the electric current and a thermoelectric effect of the semiconductor material. When the electric current passes through the semiconductor material, a side of the semiconductor material becomes hot while another side of the semiconductor material becomes cold, for a reason that charge carriers in the semiconductor material transfer energy under an influence of a thermoelectric field. By utilizing this effect, heat can be transferred from the cold side to the hot side, achieving the refrigeration effect.

In this embodiment, the semiconductor cooling element 124 has the cold end thermally connected to the inverter 30 and the hot end thermally connected to the heat dissipation structure 12. Air at the hot end of the semiconductor cooling element 124 is transferred to the ambient environment through the heat dissipation structure 12 and the fan 40, which achieves a purpose of cooling at the cold end and thus lowers the temperature of the inverter 30, ensuring the cooling performance of the energy storage power supply 100.

Further, since the semiconductor cooling element 124 allows for precise temperature control, a temperature of the shell 10 can be intelligently adjusted based on needs of the user through adjusting power consumption parameters of the semiconductor cooling element 124, enhancing experience of the user.

With reference to FIG. 7, the heat dissipation structure 12 further includes an insulation member 125 surrounding the semiconductor cooling element 124. It should be understood that, since the semiconductor cooling element 124 performs cooling at an end of the semiconductor cooling element 124 and heating at another end of the semiconductor cooling element 124 during operation, it is necessary to use the insulation member 125 to provide thermal insulation and prevent external influences on performance of the semiconductor cooling element 124. The insulation member 125 should be made of an insulation material having low thermal conductivity and satisfactory compressibility, such as pearl cotton and foam. Of course, in other embodiments of the present disclosure, the material of the insulation member 125 can be adjusted as desired and is not limited to the above limitations.

Alternatively, a thickness of the insulation member 125 is determined based on compressibility of the insulation material, generally being 1.5 times to 2 times a thickness of the semiconductor cooling element 124. The insulation member 125 fills a space between the inverter 30 and the heat dissipation structure 12, in such a manner that a compression force applied by the heat dissipation structure 12 from bottom to top enables the insulation member 125 to fill in the space in a compressed manner, ensuring satisfactory thermal insulation.

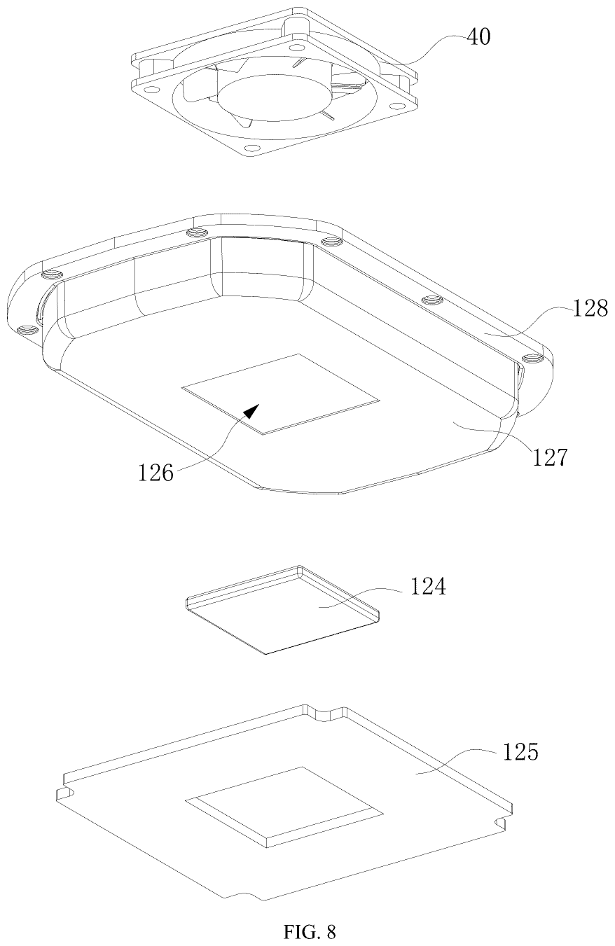

With reference to FIG. 8, in some embodiments, the heat dissipation structure 12 has a mounting recess 126 at a side of the heat dissipation structure 12 facing towards the inverter 30, and the semiconductor cooling element 124 is mounted in the mounting recess 126.

It should be understood that, since the heat dissipation structure 12 serves as a support for both the semiconductor cooling element 124 and the fan 40, the heat dissipation structure 12, the semiconductor cooling element 124, and the fan 40 can form a heat dissipation entirety, facilitating the assembly. Mounting the semiconductor cooling element 124 in the mounting recess 126 can increase a contact area between the hot end of the semiconductor cooling element 124 and the heat dissipation structure 12, improving the heat dissipation performance of the heat dissipation structure 12 for the hot end of the semiconductor cooling element 124.

Alternatively, the mounting recess 126 has a size slightly greater than that of the semiconductor cooling element 124 and a depth ranging from 0.1 mm to 0.2 mm. The mounting recess 126 is primarily for positioning the semiconductor cooling element 124. A thermally conductive material, which is typically silicone grease or the like that has fluidity, is applied at parts of the mounting recess 126 and the semiconductor cooling element 124 that are in contact with each other to eliminate a thermal resistance.

With reference to FIG. 4, in some embodiments, an outer wall of the mounting chamber 11 has a heat dissipation opening 15, and the heat dissipation structure 12 is mounted at the heat dissipation opening 15.

Specifically, the heat dissipation structure 12 may be fixedly mounted at the heat dissipation opening 15 using a screw or a bolt.

In this way, the heat dissipation structure 12 of the present disclosure can be mounted at the heat dissipation opening 15 in the outer wall of the mounting chamber 11, facilitating the heat dissipation for the inverter 30 through the heat dissipation opening 15.

With reference to FIG. 4 and FIG. 8, in some embodiments, the heat dissipation structure 12 may include a mounting portion 127 and a fixing flange 128 arranged around the mounting portion 127. The mounting portion 127 extends into the heat dissipation opening 15. The semiconductor cooling element 124 is mounted at the mounting portion 127. The fixing flange 128 is fixed on the outer wall of the mounting chamber 11 by a connector to close the heat dissipation opening 15 through the heat dissipation structure 12.

It should be understood that, the heat dissipation structure 12 serves as an independent module locked and attached to the outer wall of the mounting chamber. On one hand, the heat dissipation structure 12 is prevented from being visible from the outer side of the energy storage power supply to obtain the aesthetically pleasing appearance. On the other hand, the cold end of the semiconductor cooling element 124 can be tightly attached to the inverter 30 to improve the cooling effect on the inverter 30.

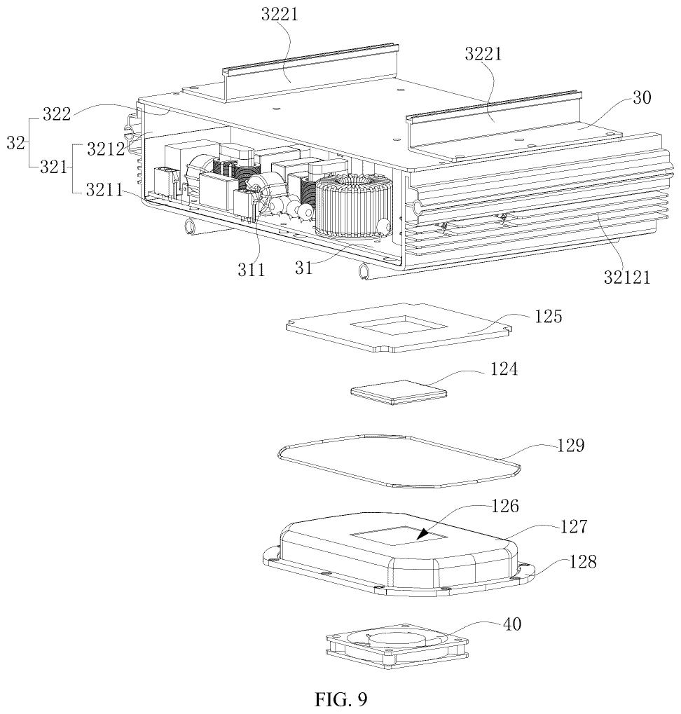

Alternatively, as illustrated in FIG. 9, a seal 129 is arranged around the mounting portion 127. An outer side wall of the seal 129 abuts with an inner wall of the heat dissipation opening 15 of the shell 10. Therefore, sealing performance of a connection between the heat dissipation structure 12 and the shell 10 can be improved to prevent external contaminants or liquids from entering the energy storage power supply 100, reducing a failure rate of the energy storage power supply 100.

Alternatively, the heat dissipation structure 12 is a single-piece die-cast member. In this way, the heat dissipation fin 121, the mounting portion 127, and the fixing flange 128 can be integrally formed, which facilitates manufacturing and weight reduction of the heat dissipation structure 12, contributing to a lightweight design of the energy storage power supply.

With reference to FIG. 9, in some embodiments, the energy storage power supply 100 further includes a heat dissipation support 32. The inverter 30 includes a circuit board 31 provided with a power component 311. The heat dissipation support 32 is mounted at the shell 10, configured to fix the circuit board 31, and thermally coupled to the power component 311. The heat dissipation support 32 is further thermally coupled to the heat dissipation structure 12.

It should be understood that fixing the circuit board 31 to the heat dissipation support 32 can protect the power component 311. The heat dissipation support 32 is thermally connected to each of the circuit board 31 and the heat dissipation structure 12. During actual operation, heat generated by the power component 311 at the circuit board 31 can be transferred from the circuit board 31 to the heat dissipation support 32, and then dissipated to the ambient environment through the heat dissipation structure 12 and the fan 40, which can improve the cooling effect on the inverter 30, ensuring the heat dissipation performance of the energy storage power supply 100.

Optionally, the heat dissipation support 32 is provided with a heat dissipation winglet 32121. The heat dissipation winglet 32121 disposed at the heat dissipation support 32 can enable heat dissipation, and work in conjunction with the heat dissipation structure 12 to ensure the cooling effect on the inverter 30, ensuring satisfactory heat dissipation functionality for the energy storage power supply 100. In the embodiments of the present disclosure, a quantity and an area of the heat dissipation winglet 32121 can be determined as desired to enable the heat dissipation winglet 32121 to have a relatively small area while ensuring heat dissipation performance of the heat dissipation winglet 32121, facilitating the lightweight design of the energy storage power supply.

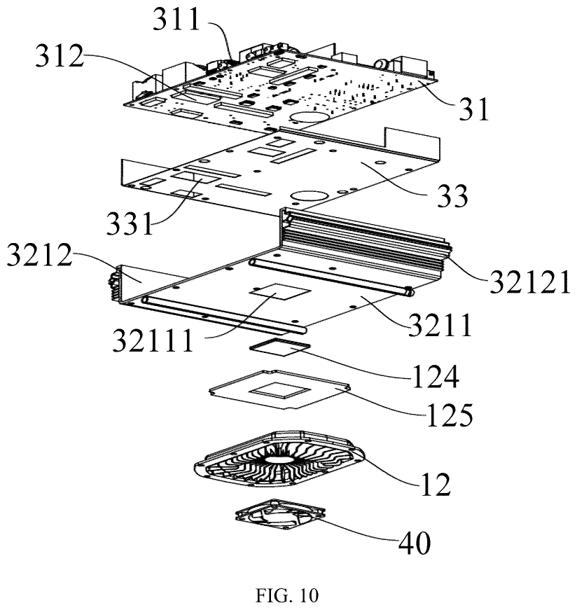

With reference to FIG. 10, in some embodiments, the heat dissipation support 32 includes a base 321 and a second cover plate 322. The base 321 includes a second bottom plate 3211 and two second side plates 3212. The two second side plates 3212 are connected to two ends of the second bottom plate 3211, respectively. A thermal conductive pad 312 is disposed between the second bottom plate 3211 and the power component 311. The second cover plate 322 is connected to the two second side plates 3212, and is provided with a limiting member 3221 configured to limit the battery module 20.

It should be understood that, as illustrated in FIG. 9, the base 321 is formed as a U-shaped plate, and the thermal conductive pad 312 is disposed between the second bottom plate 3211 and the circuit board 31. The heat dissipation winglet 32121 is disposed at the second side plate 3212. With the thermal conductive pad 312, heat generated by the power component 311 at the circuit board 31 during operation can be rapidly conducted to the heat dissipation support 32 and then quickly dissipated through the heat dissipation winglet 32121, ensuring heat dissipation performance for the circuit board 31.

The second cover plate 322 is provided with the limiting member 3221 configured to limit the battery module 20. On one hand, the limiting member 3221 can prevent the inverter 30 from shaking relative to the battery module 20; on the other hand, the limiting member 3221 can provide positioning for mounting of the inverter 30, enhancing convenience of the assembly while also improving reliability of the energy storage power supply.

Alternatively, with reference to FIG. 10, the second bottom plate 3211 has an receiving recess 32111 for receiving the semiconductor cooling element 124. The receiving recess 32111 has a size slightly greater than that of the semiconductor cooling element 124 and a depth ranging from 0.1 mm to 0.2 mm. The receiving recess 32111 is primarily for positioning the semiconductor cooling element 124. A thermally conductive material, which is typically silicone grease or the like that has fluidity, is applied at parts of the receiving recess 32111 and the semiconductor cooling element 124 that are in contact with each other to eliminate the thermal resistance. In this way, not only can positioning of the semiconductor cooling element 124 be enhanced, but also heat dissipation performance of the semiconductor cooling element 124 on the heat dissipation support 32 can be improved.

Alternatively, with reference to FIG. 10, the inverter 30 further includes an insulation plate 33. The insulation plate 33 is sandwiched between the second bottom plate 3211 and the circuit board 31, and has an avoidance hole 351 corresponding to the thermal conductive pad 312. It should be understood that the added insulation plate 33 can ensure insulation between the circuit board 31 and the second bottom plate 3211 to prevent short circuits caused by electrification of the heat dissipation support 32, improving operational reliability of the energy storage power supply. The avoidance hole 351 at the insulation plate 33 can ensure that the thermal conductive pad 312 directly abuts with the second bottom plate 3211, which guarantees that heat from the circuit board 31 can be rapidly conducted to the heat dissipation support 32, improving the heat dissipation efficiency of the inverter 30.

In some embodiments, the energy storage power supply 100 further includes a heat pipe thermally coupled to the heat dissipation structure 12.

Specifically, the heat pipe is usually a sealed copper pipe containing a phase change medium inside and has high thermal conductivity. In the present disclosure, the heat pipe is disposed in the receiving cavity 132 and attached to the heat dissipation structure 12. Heat mainly originates from the inverter 30, but different power components 311 of the inverter 30 generate varying amounts of heat, which is likely to lead to an uneven temperature distribution across different regions of the heat dissipation structure 12, possibly resulting in an extremely-high-temperature region.

Therefore, in the present disclosure, the heat pipe can guide the heat from a high-temperature region to a low-temperature region to achieve even heat dissipation of the heat dissipation structure 12 for better heat dissipation, realizing the satisfactory heat dissipation performance.

With reference to FIG. 2, in some embodiments, the battery module 20 may be disposed above the inverter 30, and the battery module 20 may be provided with a protection board 21 at a surface of the battery module 20 facing towards the inverter 30. The protection board 21 is used for protecting the battery module 20.

In detail, the protection board 21 can prevent the inverter 30 or other external objects from coming into direct contact with the battery module 20 to avoid potential physical damage due to friction, collision, or compression, which is crucial for maintaining structural integrity of the battery module 20 and prolonging a lifespan of the battery module 20.

Additionally, in some cases, the inverter 30 is likely to produce electromagnetic interferences or electrical noises. The protection board 21 can serve as an electrical barrier to reduce an impact of these interferences on the battery module 20, ensuring stable and safe operation of the battery module 20.

In addition, the battery module 20 generates heat during operation, and the inverter 30 can also be a heat source. The protection board 21 can provide a certain degree of thermal insulation to reduce thermal exchange between the battery module 20 and the inverter 30, which helps to maintain the battery module within an appropriate operation temperature range.

When the inverter 30 experiences a fault or an abnormal condition such as a short circuit or overheating, the protection board 21 can act as an additional safety barrier, preventing these issues from directly damaging the battery module 20. Further, the protection board 21 can mitigate a risk of safety hazards such as fire or explosion to a certain extent.

While several embodiments of the present disclosure have been described above in a specific and detailed manner, the protection scope of the present disclosure cannot be construed as being limited to these embodiments. It should be noted that, those skilled in the art can make various variants and improvements without departing from the concept of the present disclosure, and these variants and improvements shall fall within the protection scope of present disclosure as defined by the claims as appended.

What is claimed is:

1. An energy storage power supply, comprising:
a shell having a mounting chamber and provided with a heat dissipation structure;
a battery module mounted in the mounting chamber;
an inverter mounted in the mounting chamber, the inverter being thermally coupled to the heat dissipation structure and electrically connected to the battery module; and
a fan mounted at an outer side of the shell, the fan being configured to generate flowing air that flows through the heat dissipation structure.

2. The energy storage power supply according to claim 1, wherein the heat dissipation structure comprises a plurality of heat dissipation fins disposed at a bottom, and/or a side surface, and/or a top of the shell.

3. The energy storage power supply according to claim 2, wherein the plurality of heat dissipation fins are arranged in a radial pattern and have a mounting space formed in a center of the plurality of heat dissipation fins, the fan being mounted in the mounting space.

4. The energy storage power supply according to claim 2, wherein:
the plurality of heat dissipation fins are arranged at a gradient in which an arrangement density of the plurality of heat dissipation fins gradually decreases from a center of the plurality of heat dissipation fins to a periphery of the plurality of heat dissipation fins; and
the plurality of heat dissipation fins are arranged at a gradient in which an arrangement height of the plurality of heat dissipation fins gradually increases from the center of the plurality of heat dissipation fins to the periphery of the plurality of heat dissipation fins.

5. The energy storage power supply according to claim 1, wherein the fan is a centrifugal fan or an axial flow fan.

6. The energy storage power supply according to claim 1, wherein the heat dissipation structure comprises a protrusion located in the mounting chamber and fixed on the shell, the protrusion being thermally coupled to a power component of the inverter.

7. The energy storage power supply according to claim 6, wherein a thermal conductive layer is disposed between the protrusion and the power component, the protrusion being thermally coupled to the power component of the inverter through the thermal conductive layer.

8. The energy storage power supply according to claim 1, further comprising a foot pad disposed at a bottom of the shell, the foot pad being configured to be in contact with an external supporting surface to space the bottom of the shell apart from the external supporting surface.

9. The energy storage power supply according to claim 1, further comprising a first cover plate fixedly mounted at the outer side of the shell and covering the fan, the first cover plate having a ventilation hole.

10. The energy storage power supply according to claim 9, wherein:
the first cover plate covers the heat dissipation structure, and comprises a first bottom plate and a first side plate surrounding the first bottom plate, an air channel being formed between the heat dissipation structure and the first cover plate; and
the ventilation hole comprises a first ventilation hole formed at the first bottom plate and a second ventilation hole formed at the first side plate, the air channel being formed between the first ventilation hole and the second ventilation hole.

11. The energy storage power supply according to claim 9, further comprising a foot pad disposed at a side of the first cover plate facing away from the fan, the foot pad being configured to be in contact with an external supporting surface to space a bottom of the first cover plate apart from the external supporting surface.

12. The energy storage power supply according to claim 9, further comprising a foot pad, wherein:
a through hole corresponding to the foot pad is formed at a bottom plate of the first cover plate, the foot pad passing through the through hole and the shell to be fixedly disposed at a bottom of the first cover plate; and
the foot pad is configured to be in contact with an external supporting surface to space the bottom of the first cover plate apart from the external supporting surface.

13. The energy storage power supply according to claim 1, wherein the shell comprises a first housing and a second housing, the first housing and the second housing being assembled with each other to form the mounting chamber, wherein:
the inverter is fixed on the first housing;
the heat dissipation structure is disposed at the first housing; and
the battery module is fixed on the second housing.

14. The energy storage power supply according to claim 13, wherein the first housing is an aluminum alloy housing, the first housing being thermally coupled to the inverter at an inner side of the first housing, and the heat dissipation structure being disposed at an outer side of the first housing.

15. The energy storage power supply according to claim 13, wherein the first housing has a receiving cavity, the inverter being fixedly mounted in the receiving cavity.

16. The energy storage power supply according to claim 13, wherein the second housing is provided with a panel having a power output port.

17. The energy storage power supply according to claim 1, wherein a temperature sensor is mounted at the heat dissipation structure to detect a temperature of the heat dissipation structure, the energy storage power supply being configured to control activation of the fan, deactivation of the fan, or a rotational speed of the fan based on the temperature of the heat dissipation structure.

18. The energy storage power supply according to claim 1, further comprising a semiconductor cooling element having a hot end thermally coupled to the heat dissipation structure and a cold end thermally coupled to the inverter.
